(19) United States
(12) Patent Application Publication
(10) Pub. No.: US 2025/0359305 A1
(43) Pub. Date: Nov. 20, 2025

(54) STRESS LINER COMPATIBLE WITH OXIDE SPACER

(71) Applicant: Micron Technology, Inc., Boise, ID (US)

(72) Inventors: Bingwu Liu, Meridian, ID (US); Tao Duy Nguyen, Boise, ID (US)

(21) Appl. No.: 19/204,163

(22) Filed: May 9, 2025

Related U.S. Application Data
(60) Provisional application No. 63/647,428, filed on May 14, 2024.

(51) Int. Cl. H10D 84/83

(52) U.S. Cl. CPC H10D 84/83138

(57) ABSTRACT

A variety of applications can include memory devices implementing CMOS devices in the periphery to the memory array of the memory devices and in sense amplifiers to the memory array. The CMOS devices can include a gate structure having a dielectric sidewall with an oxide sidewall on and contacting the dielectric sidewall and with a stress liner on and contacting the oxide sidewall. The oxide sidewall can be larger than the dielectric sidewall. In fabrication of the CM OS devices, a dielectric such as a nitride can be implemented as outer material that is sacrificial, while an oxide sidewall is maintained such that the spacer between the gates of the CMOS devices and the stress liner in the periphery is substantially the oxide sidewall.

### PRIORITY APPLICATION

This application claims the benefit of priority to U.S. Provisional Application Ser. No. 63/647,428, filed May 14, 2024, which is incorporated herein by reference in its entirety.

### FIELD OF THE DISCLOSURE

Embodiments of the disclosure relate generally to electronic devices and systems and, more specifically, to transistors of electronic devices and systems and formation thereof.

### BACKGROUND

Memory devices are typically provided as internal, semiconductor, integrated circuits in computers or other electronic devices. There are many different types of memory, including volatile and non-volatile memory. Volatile memory requires power to maintain its data, and includes random-access memory (RAM), dynamic random-access memory (DRAM), static RAM (SRAM), or synchronous dynamic random-access memory (SDRAM), among others. Non-volatile memory can retain stored data when not powered, and includes flash memory, read-only memory (ROM), electrically erasable programmable ROM (EEPROM), erasable programmable ROM (EPROM), resistance variable memory, such as phase-change random-access memory (PCRAM), resistive random-access memory (RRAM), magnetoresistive random-access memory (M RAM), or three-dimensional (3D) XPoint™ memory, among others. Properties of memory devices can be improved by enhancements to the design and fabrication of components of the memory devices.

### BRIEF DESCRIPTION OF THE DRAWINGS

The drawings, which are not necessarily drawn to scale, illustrate generally, by way of example, but not by way of limitation, various embodiments discussed in the present document.

FIG. 1 is a flow diagram of features of an example method of forming a memory device, in accordance with various embodiments.

FIG. 2 is a flow diagram of features of an example method of forming a memory device, in accordance with various embodiments.

FIGS. 3-16 illustrate features of example processing of complementary metal oxide semiconductor devices in a periphery to an array of memory cells and in a sense amplifier for the array, in accordance with various embodiments.

FIG. 17 illustrates a block diagram of an example memory device including a memory array having a plurality of memory cells, a periphery to the memory array, sense amplifiers, and one or more circuits or components to provide communication with the memory array or perform one or more memory operations on the memory array, according to various embodiments.

FIG. 18 is a block diagram illustrating an example of a machine in which one or more memory devices may be implemented, in accordance with various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments may be utilized, and structural, logical, mechanical, and electrical changes may be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above. Various features can have a vertical component to the direction of their structure. The various embodiments are not necessarily mutually exclusive, as some embodiments can be combined with one or more other embodiments to form new embodiments. The following detailed description is, therefore, not to be taken in a limiting sense.

Memory devices can include one or more arrays of memory cells, control circuitry for managing and accessing the memory cells, and sense amplifiers for reading data encapsulated by the memory cells. The control circuitry for managing and accessing the array of memory cells can be in a periphery to the one or more arrays of memory cells, where the periphery is separate from sense amplifiers that function as the circuitry for reading data status of the memory cells. The periphery and the sense amplifiers can be constructed with complementary metal oxide semiconductor (CM OS) devices.

An oxide spacer to gates of transistors in a CM OS device in a memory device is a key parameter to reduce parasitic capacitance in the CM OS device to boost alternating current (AC) performance of the CM OS device in a memory device such as, but not limited to, a DRAM. A spacer is the sidewall material outside the gates of the transistors of the CMOS devices, where the gates can be polysilicon or metal. The spacer material is dielectric that contributes to parasitic capacitance of gates and corresponding contacts. For management of parasitic capacitance, a low dielectric constant, k, of the spacer can provide lower parasitic capacitance, which can enhance the speed of a ring oscillator (RO) of a DRAM, for example. A RO can measure performance of a DRAM storage cell.

A stress liner is widely used to boost the CM OS direct current (DC) performance of the CMOS device by changing the channel stress through depositing a stress liner. The stress liner can be positioned on and contacting the spacer to the CM OS transistors. Such a stress liner is usually, but not limited to, a nitride stress liner, where the stress liner is structured to provide a tensile stress for a n-channel field effect transistor (N FET) and a compressive stress for a p-channel field effect transistor (PFET). To maximize the stress effect, the stress liner should be as close to the transistor channel as possible. In fabrication, a conventional processing technique is to remove an oxide spacer post dopant implant of the source/drain transistors before stress liner deposition. However, there is some effects associated with the combination of the oxide spacer with stress liner. During the oxide spacer removal, the oxide of a shallow trench isolation (STI) between CMOS in different regions of the integrated circuit being fabricated can also be subjected to material lost, which may induce interlayer dielectric (ILD) fill, electrical shorting issues for the device being fabricated, or a contact touching a junction of a transistor of the CM OS device that can induce high junction leakage. Because of oxide removal, the average value of the dielectric constant (k) of the spacer is increased that will increase the parasitic capacitance, which impacts the A C performance.

In various embodiments, a spacer scheme can be implemented that can resolve the abovementioned issues associated with the conventional processing techniques. This spacer scheme can retain the benefit from both an oxide spacer and a stress liner. Such an oxide spacer scheme that is compatible with a nitride stress liner process, for example, can maximize the capacitance and stress benefit. The spacer scheme can lower capacitance for AC performance and provide highest stress effect to boost DC performance. The conventional process uses a nitride as inner spacer and an oxide as an outer spacer, where an outer oxide spacer is also used in a sacrificial manner in fabrication. The spacer scheme, taught herein, uses a nitride spacer as outer material, which is sacrificial in fabrication, and an oxide spacer is kept at final processing of the outer material, which can make the final spacer substantially an oxide instead of nitride or other dielectric material. In such a spacer between the conductive gate and the stress liner, the spacer can have an oxide composition from 60 to 90 percentage of the spacer composed of initial spacer on the gate of a gate structure and an oxide spacer. The combination of spacer and stress liner can have an oxide composition from 60 to 90 percentage of the combination. In some instances, the combination of oxide spacer and stress liner can have an oxide composition from 40 to 90 percentage of the combination.

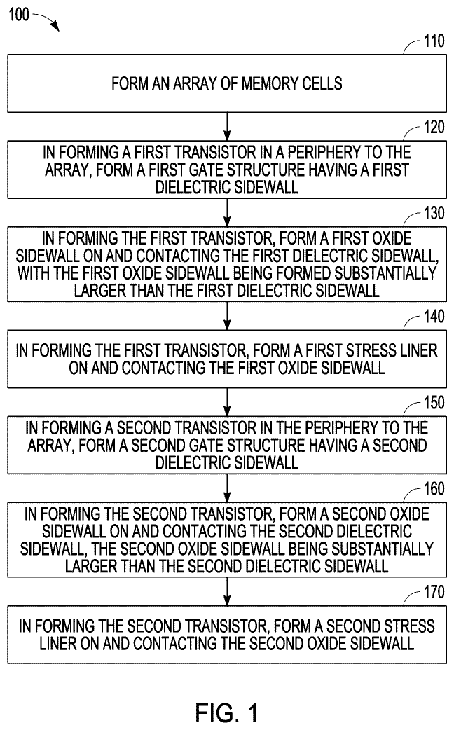

FIG. 1 is a flow diagram of features of an embodiment of an example method of forming a memory device. At 110, an array of memory cells is formed, and a first transistor and a second transistor are formed in a periphery to the array. At 120, in forming the first transistor in the periphery to the array, a first gate structure is formed having a first dielectric sidewall. The first dielectric sidewall can be, but is not limited to, a nitride. The nitride can be silicon nitride. At 130, in forming the first transistor, a first oxide sidewall is formed on and contacting the first dielectric sidewall, with the first oxide sidewall being formed substantially larger than the first dielectric sidewall. At 140, in forming the first transistor, a first stress liner is formed on and contacting the first oxide sidewall. The first stress liner can be a dielectric.

At 150, in forming the second transistor in the periphery to the array, a second gate structure is formed having a second dielectric sidewall. The second dielectric sidewall can be, but is not limited to, a nitride. The nitride can be silicon nitride. At 160, in forming the second transistor, a second oxide sidewall is formed on and contacting the second dielectric sidewall, with the second oxide sidewall being substantially larger than the second dielectric sidewall. At 170, in forming the second transistor, a second stress liner is formed on and contacting the second oxide sidewall. The second stress liner can be a dielectric.

Variations of method 100 or methods similar to method 100 can include a number of different embodiments that may be combined depending on the application of such methods or the architecture or process flow of an integrated circuit for which such methods are implemented. Such methods can include forming a third transistor and a fourth transistor in a sense amplifier to the array. Forming the third transistor can include forming a third gate structure having a third dielectric sidewall and forming a third oxide sidewall on and contacting the third dielectric sidewall, where the third oxide sidewall is arranged without a stress liner on and contacting completion of the third oxide sidewall. The third dielectric sidewall can be, but is not limited to, a nitride. The nitride can be silicon nitride. Forming the fourth transistor can include forming a fourth gate structure having a fourth dielectric sidewall and forming a fourth oxide sidewall on and contacting the fourth dielectric sidewall, where the fourth oxide sidewall is arranged without a stress liner on and contacting completion of the fourth oxide sidewall. The fourth dielectric sidewall can be, but is not limited to, a nitride. The nitride can be silicon nitride. Variations can include forming the first transistor and the second transistor as a first CM OS device in the periphery and forming the third transistor and the fourth transistor as a second CM OS device in the sense amplifier.

Variations of method 100 or methods similar to method 100 can include forming the first oxide sidewall, the second oxide sidewall, the third oxide sidewall, and the fourth oxide sidewall having a common composition and formed in a common fabrication process. Variations can include forming a stress dielectric on the first oxide sidewall, the second oxide sidewall, the third oxide sidewall, and the fourth oxide sidewall; and removing the stress dielectric from the third oxide sidewall, and the fourth oxide sidewall. The common composition can be silicon oxide and the stress liner can include a tensile nitride.

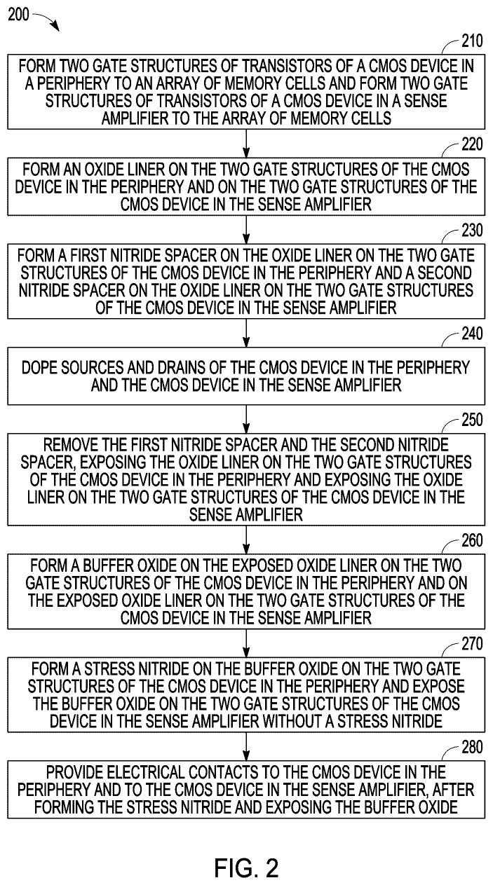

FIG. 2 is a flow diagram of features of an embodiment of an example method of forming a memory device. At 210, two gate structures of transistors of a CM OS device in a periphery to an array of memory cells are formed and two gate structures of transistors of a CMOS device in a sense amplifier to the array of memory cells are formed. At 220, an oxide liner is formed on the two gate structures of the CM OS device in the periphery and on the two gate structures of the CM OS device in the sense amplifier. At 230, a first nitride spacer is formed on the oxide liner on the two gate structures of the CM OS device in the periphery and a second nitride spacer is formed on the oxide liner on the two gate structures of the CM OS device in the sense amplifier.

At 240, sources and drains of the CM OS device in the periphery and the CMOS device in the sense amplifier are doped. The first nitride spacer and the second nitride spacer can be used in the doping procedure. At 250, the first nitride spacer and the second nitride spacer are removed, exposing the oxide liner on the two gate structures of the CM OS device in the periphery and exposing the oxide liner on the two gate structures of the CM OS device in the sense amplifier. At 260, a buffer oxide is formed on the exposed oxide liner on the two gate structures of the CM OS device in the periphery and on the exposed oxide liner on the two gate structures of the CM OS device in the sense amplifier. At 270, a stress nitride is formed on the buffer oxide on the two gate structures of the CM OS device in the periphery. The buffer oxide on the two gate structures of the CMOS device in the sense amplifier is exposed without a stress nitride. The stress nitride can include a tensile nitride. At 280, electrical contacts are provided to the CM OS device in the periphery and to the CM OS device in the sense amplifier, after forming the stress nitride and exposing the buffer oxide.

Variations of method 200 or methods similar to method 200 can include a number of different embodiments that may be combined depending on the application of such methods or the architecture or process flow of an integrated circuit for which such methods are implemented. Such methods can include forming a spacer for lightly doped drains to the transistors of the CM OS device in the periphery and for lightly doped drains to the transistors of the CM OS device in the sense amplifier. The spacer for the lightly doped drains can be removed from horizontal surfaces between the transistors of the CM OS device in the periphery and from horizontal surfaces between the transistors of the CM OS device in the sense amplifier. Lightly doped drain implants can be formed between the transistors of the CM OS device in the periphery and between the transistors of the CMOS device in the sense amplifier. The spacer for the lightly doped drains to the transistors can remain as part of a spacer between gates of the transistors in the periphery in combination with the buffer oxide. If the buffer oxide is not formed due to the previously formed oxide liner being of sufficient thickness, the spacer can be realized by oxide liner and the spacer for the lightly doped drains.

Variations of method 200 or methods similar to method 200 can include forming the first nitride spacer and the second nitride spacer by performing a number of process procedures. A first nitride region can be formed on the oxide liner on the two gate structures of the CMOS device in the periphery, on the oxide liner on the two gate structures of the CM OS device in the sense amplifier, on horizontal surface between the two gate structures of the CM OS device in the periphery, and on horizontal surfaces between the two gate structures of the CMOS device in the sense amplifier. The first nitride region can be removed from the horizontal surface between the two gate structures of the CM OS device in the periphery and from the sense amplifier. A second nitride region can be formed on the first nitride region on the oxide liner on the two gate structures of the CM OS device in the periphery, on the horizontal surface between the two gate structures of the CM OS device in the periphery, on the horizontal surface between the two gate structures of the CM OS device in the sense amplifier, and on the oxide liner on the two gate structures of the CM OS device in the sense amplifier. The second nitride region can be removed from the horizontal surface between the two gate structures of the CM OS device in the periphery and from the horizontal surface between the two gate structures of the CM OS device in the sense amplifier.

Variations of method 200 or methods similar to method 200 can include forming the stress nitride in the periphery and exposing the buffer oxide in the sense amplifier without a stress nitride by a number of process procedures. A stress nitride region can be formed above and between the gate structures of the CM OS device in the periphery and above and between the gate structures of the CM OS device in the sense amplifier. The stress nitride region can be removed from between the gate structures of the CM OS device in the periphery. The stress nitride region can be removed from the sense amplifier.

Variations of method 200 or methods similar to method 200 can include forming the stress nitride on the buffer oxide on the two gate structures of the CM OS device in the sense amplifier and forming the stress nitride on a horizontal surface between the two gate structures of the CM OS device in the periphery and on a horizontal surface between the two gate structures of the CMOS device in the sense amplifier. The stress nitride can be removed from the buffer oxide on the two gate structures of the CM OS device in the sense amplifier, from the horizontal surface between the two gate structures of the CM OS device in the periphery, and from the horizontal surface between the two gate structures of the CM OS device in the sense amplifier. A nitride region can be formed on the stress nitride in the CM OS device in the sense amplifier and on the buffer oxide on the two gate structures of the CM OS device in the sense amplifier. The electrical contacts can be formed through the nitride region and the buffer oxide on the horizontal surfaces between the two transistors of the CM OS device in the periphery and the two transistors of the CM OS device in the sense amplifier.

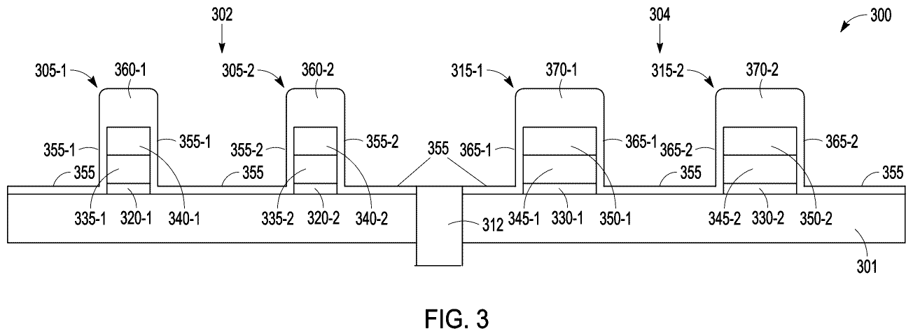

FIGS. 3-16 illustrate features of example processing of CM OS devices in a periphery 302 to an array of memory cells and in a sense amplifier 304 for the array. FIG. 3 represents a cross-sectional view of a structure 300 having a first gate structure 305-1 and a second gate structure 305-2 for a CMOS device in periphery 302 and a third gate structure 315-1 and a fourth gate structure 315-2 for a CM OS device in sense amplifier 304. Periphery 302 is being fabricated to include control circuitry for managing and accessing the array of memory cells. Sense amplifier 304 is being fabricated to function as the circuitry for reading data status of the memory cells.

First gate structure 305-1 for a first transistor of the CM OS device in periphery 302 has been formed with a gate dielectric 320-1 on a channel structure in substrate 301. A gate having a polysilicon region 335-1 with a metal region 340-1 thereon has been formed on gate dielectric 320-1. A dielectric cap 360-1 has been formed on and above metal region 340-1 and a dielectric sidewall 355-1 has been formed to the combined structure of gate dielectric 320-1, polysilicon region 335-1, and metal region 340-1.

Second gate structure 305-2 for a second transistor of the CM OS device in periphery 302 has been formed with a gate dielectric 320-2 on a channel structure in substrate 301. A gate having a polysilicon region 335-2 with a metal region 340-2 thereon has been formed on gate dielectric 320-2. A dielectric cap 360-2 has been formed on and above metal region 340-2 and a dielectric sidewall 355-2 has been formed to the combined structure of gate dielectric 320-2, polysilicon region 335-2, and metal region 340-2.

Third gate structure 315-1 for a first transistor of the CM OS device in sense amplifier 304 has been formed with a gate dielectric 330-1 on a channel structure in substrate 301. A gate having a polysilicon region 345-1 with a metal region 350-1 thereon has been formed on gate dielectric 330-1. A dielectric cap 370-1 has been formed on and above metal region 350-1 and a dielectric sidewall 365-1 has been formed to the combined structure of gate dielectric 330-1, polysilicon region 345-1, and metal region 350-1.

Fourth gate structure 315-2 for a second transistor of the CM OS device in sense amplifier 304 has been formed with a gate dielectric 330-2 on a channel structure in substrate 301. A gate having a polysilicon region 345-2 with a metal region 350-2 thereon has been formed on gate dielectric 330-2. A dielectric cap 370-2 has been formed on and above metal region 350-2 and a dielectric sidewall 365-2 has been formed to the combined structure of gate dielectric 330-2, polysilicon region 345-2, and metal region 350-2.

A STI 312 has been formed between periphery 302 and sense amplifier 304. A dielectric layer 355 has been formed on the surface of substrate 301. Dielectric layer 355 and dielectric sidewalls 355-1, 355-2, 365-1, and 365-2 have been formed as part of formation of a spacer for lightly doped drains (LDDs). Dielectric layer 355, dielectric sidewalls 355-1, 355-2, 365-1, and 365-2, and dielectric caps 360-1, 360-2, 370-1, and 370-2 can be formed of a common composition. The common composition can be a nitride such as, but not limited to, silicon nitride. Alternatively, dielectric layer 355, dielectric sidewalls 355-1, 355-2, 365-1, and 365-2, and dielectric caps 360-1, 360-2, 370-1, and 370-2 can have a permutation of different dielectric materials. Substrate 301, on which first gate structure 305-1, second gate structure 305-2, third gate structure 315-1, and fourth gate structure 315-2 are structured, can be, but is not limited to, a silicon substrate. Gate dielectrics 320-1, 320-2, 330-1, and 330-2 can be a silicon oxide, one or more high-k dielectrics, or combinations thereof. Each of metal regions 340-1, 340-2, 350-1, and 350-2 can include one or more of tungsten (W), titanium (Ti), tungsten nitride (WN), titanium nitride (TiN), tungsten silicide (W Si_{X}), and ruthenium (Ru). STI 312 can be an oxide or can be formed of the same composition as one of gate dielectrics 320-1, 320-2, 330-1, and 330-2.

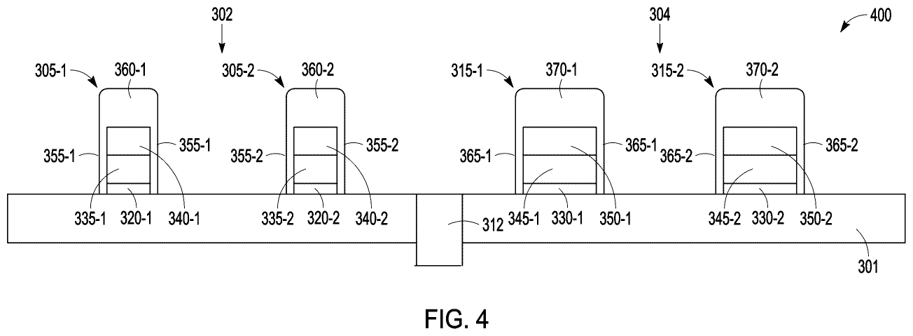

FIG. 4 represents a cross-sectional view of a structure 400 after further processing structure 300 of FIG. 3. The LDD spacer has been removed in a number of locations. Dielectric layer 355 has been removed while maintaining sufficient amounts of dielectric sidewalls 355-1, 355-2, 365-1, and 365-2. The removal can be conducted by an appropriate etch.

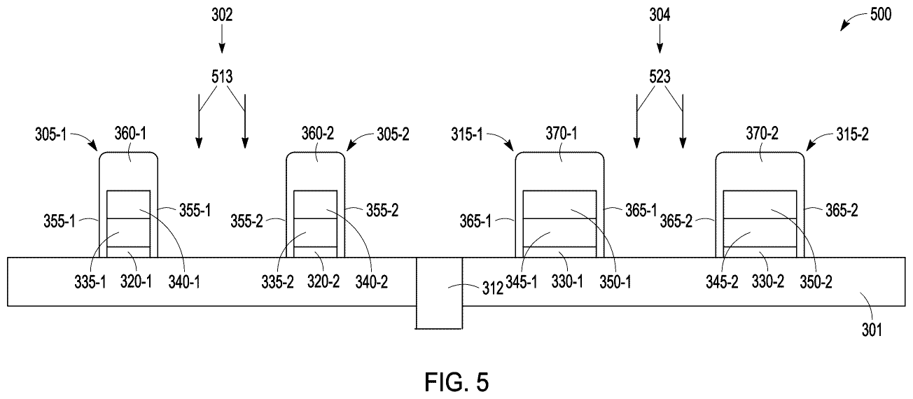

FIG. 5 represents a cross-sectional view of a structure 500 after further processing structure 400 of FIG. 4. LDD implants 513 have been provided for the transistors of the CMOS device in periphery 302 and LDD implants 523 have bee provided for the transistors of the CMOS device in sense amplifier 304.

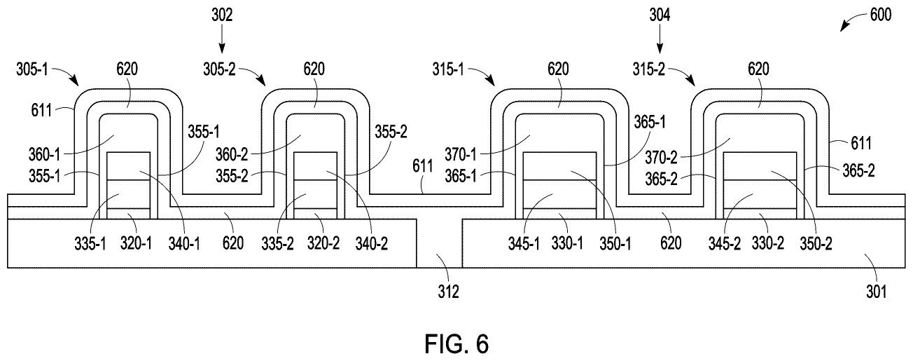

FIG. 6 represents a cross-sectional view of a structure 600 after further processing structure 500 of FIG. 5. An oxide liner 620 has been formed on first gate structure 305-1 and second gate structure 305-2 in periphery 302 and on third gate structure 315-1 and fourth gate structure 315-2 in sense amplifier 304. Oxide liner 620 has also been formed on the horizontal surfaces of structure 500 of periphery 302 and sense amplifier 304 between the gate structures. A dielectric spacer 611 has been formed on and contacting oxide liner 620. Oxide liner 620 can be, but is not limited to, silicon oxide. Dielectric spacer 611 can be a deposited nitride spacer but is not limited to a nitride. Other materials that are selective to oxide liner 620 can be used. A material selective to oxide is a material in which removal of the material or the oxide can be accomplished without significant removal of the other. In conventional processes, a nitride spacer is formed directly on the gate structures, the gate structures including a LDD spacer, followed by an oxide liner on the nitride spacer.

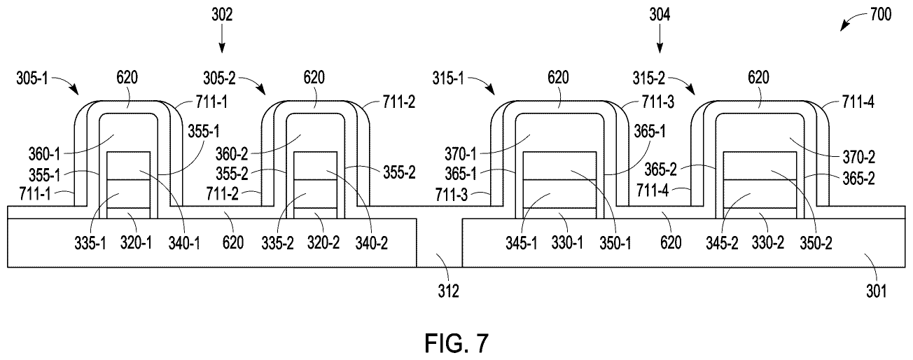

FIG. 7 represents a cross-sectional view of a structure 700 after further processing structure 600 of FIG. 6. Dielectric spacer 611 has been removed from horizontal surfaces of structure 600, leaving a vertical dielectric spacer 711-1 on oxide liner 620 on first gate structure 305-1 and a vertical dielectric spacer 711-2 on oxide liner 620 on second gate structure 305-2 in periphery 302, and leaving a vertical dielectric spacer 711-3 on oxide liner 620 on third gate structure 315-1 and a vertical dielectric spacer 711-4 on oxide liner 620 on fourth gate structure 315-2 in sense amplifier 304. Removal of dielectric spacer 611 can be performed using an etch for dielectric spacer 611 being selective to oxide liner 620.

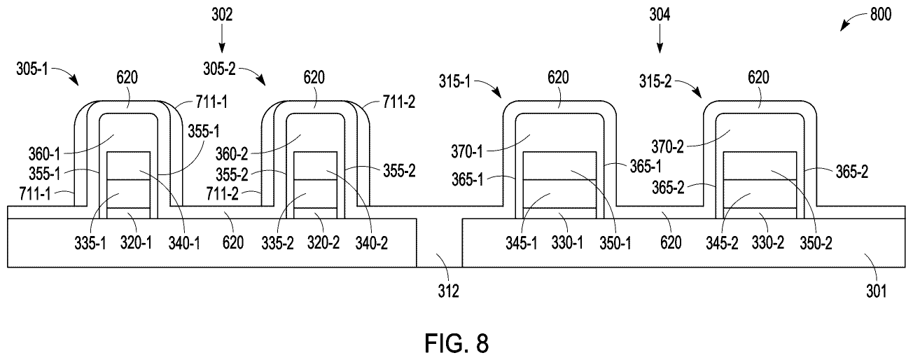

FIG. 8 represents a cross-sectional view of a structure 800 after further processing structure 700 of FIG. 7. Vertical dielectric spacer 711-3 and vertical dielectric spacer 711-4 have been removed in sense amplifier 304, leaving oxide liner 620, without removing vertical dielectric spacer 711-1 and vertical dielectric spacer 711-2 in periphery 302. Alternatively, structure 800 can be generated when forming structure 700.

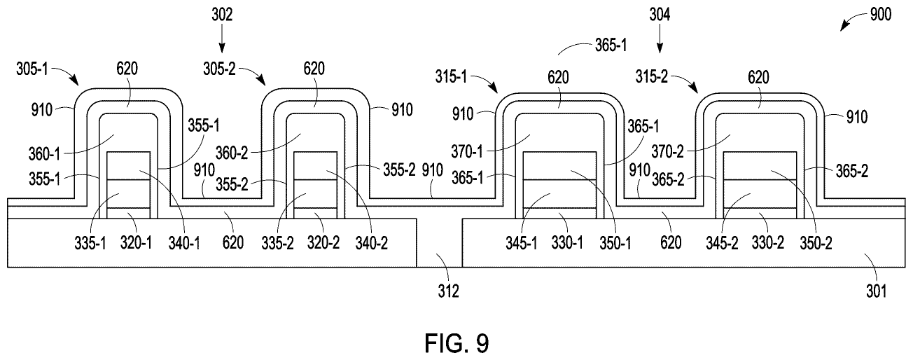

FIG. 9 represents a cross-sectional view of a structure 900 after further processing structure 800 of FIG. 8. A dielectric spacer 910 has been formed on structure 800 of FIG. 8. Dielectric spacer 910 on vertical dielectric spacer 711-1 and vertical dielectric spacer 711-2 in periphery 302 provides a thicker spacer than dielectric spacer 910 on oxide liner 320 in sense amplifier 304. The material of dielectric spacer 910 can be, but is not limited to, the material of dielectric spacers 711-1 and 711-2. Dielectric spacer 910 can be but is not limited to a nitride spacer.

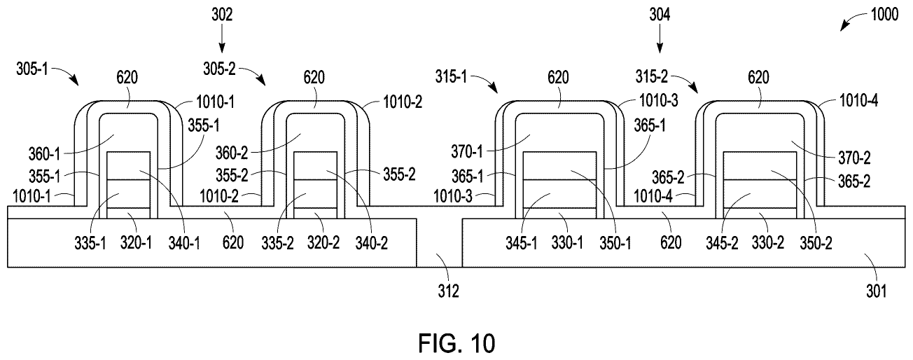

FIG. 10 represents a cross-sectional view of a structure 1000 after further processing structure 900 of FIG. 9. Dielectric spacer 910 of structure 900 has been removed from the horizontal sections on oxide liner 620, leaving a vertical dielectric spacer 1010-1 on oxide liner 620 on first gate structure 305-1 and a vertical dielectric spacer 1010-2 on oxide liner 620 on second gate structure 305-2 in periphery 302, and leaving a vertical dielectric spacer 1010-3 on oxide liner 620 on third gate structure 315-1 and a vertical dielectric spacer 1010-4 on oxide liner 620 on fourth gate structure 315-2 in sense amplifier 304. Removal of dielectric spacer 910 can be performed using an etch for dielectric spacer 611 being selective to oxide liner 620 such that oxide liner 620 remains between the gate structures of structure 1000 and vertical dielectric spacers 1010-1, 1010-2, 1010-3, and 1010-4 remain. Alternatively, oxide liner 620 between the gate structures of structure 1000 on substrate 301 can be removed.

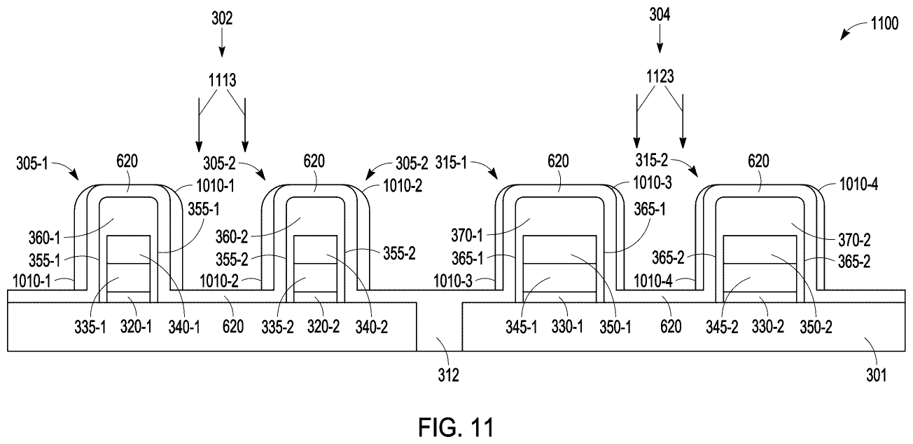

FIG. 11 represents a cross-sectional view of a structure 1100 after further processing structure 1000 of FIG. 10. Dopants 1113 have been added for the sources and drains corresponding to each of first gate structure 305-1 and second gate structure 305-2 in periphery 302. Dopants 1123 have been added for the sources and drains corresponding to third gate structure 305-3 and fourth gate structure 305-4 in sense amplifier 304. The dopants 1113 and 1123 can be implanted through oxide liner 620. Alternatively, if dielectric spacer 910 is not removed when forming structure 1000, the dopants 1113 and 1123 can be implanted through the combination of dielectric spacer 910 and oxide liner 620.

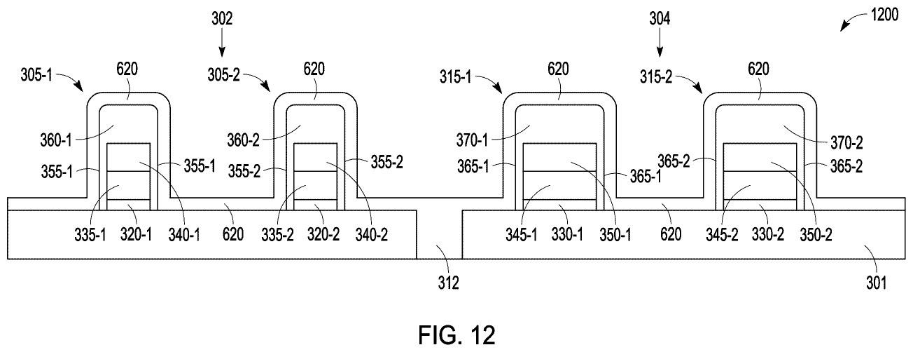

FIG. 12 represents a cross-sectional view of a structure 1200 after further processing structure 1100 of FIG. 11. Vertical dielectric spacer 1010-1, vertical dielectric spacer 1010-2, vertical dielectric spacer 1010-3, and vertical dielectric spacer 1010-4 have been removed. With selective removal of vertical dielectric spacer 1010-1, vertical dielectric spacer 1010-2, vertical dielectric spacer 1010-3, and vertical dielectric spacer 1010-4 being selective to oxide liner 620, there also is no loss of material from STI 312.

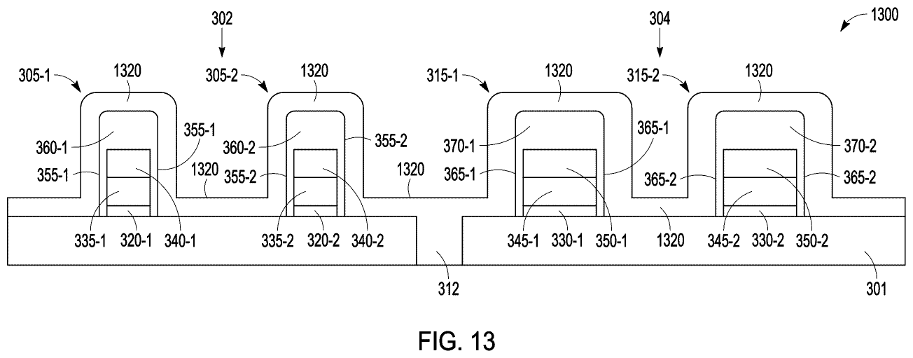

FIG. 13 represents a cross-sectional view of a structure 1300 after further processing structure 1200 of FIG. 12. A buffer oxide 1320 is formed. Buffer oxide 1320 can be formed by an appropriate deposition. If dielectric spacer etches do not remove a threshold amount of material of oxide liner 620 such that there is sufficient oxide liner 620 remaining, the procedure of formation of buffer oxide 1320 can be avoided, which reduces the number of procedures in the formation of the CM OS devices in periphery 302 and sense amplifier 304.

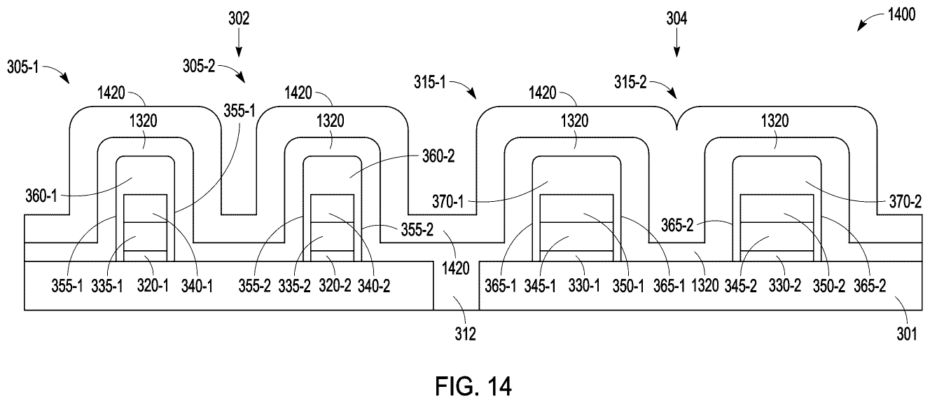

FIG. 14 represents a cross-sectional view of a structure 1400 after further processing structure 1300 of FIG. 13. A stress nitride 1420 has been formed on the surfaces of structure 1300. For a tensile nitride, a plasma-enhanced chemical vapor deposition (PECVD) process can be used to create sufficient hydrogen impurities in the nitride film. An ultraviolet (UV) cure post deposition can remove the hydrogens and stress nitride 1420 shrinks which introduces the stress.

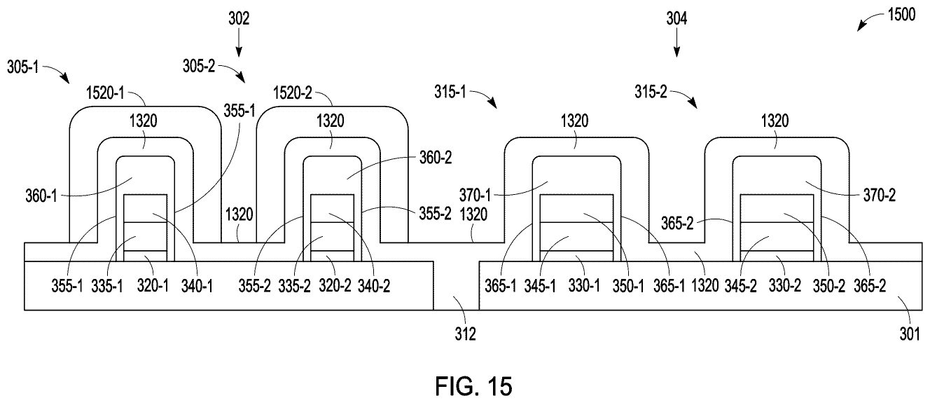

FIG. 15 represents a cross-sectional view of a structure 1500 after further processing structure 1400 of FIG. 14. Stress nitride 1420 has been removed from sense amplifier 304 including from the regions around and between third gate structure 305-3 and fourth gate structure 305-4 in sense amplifier 304.

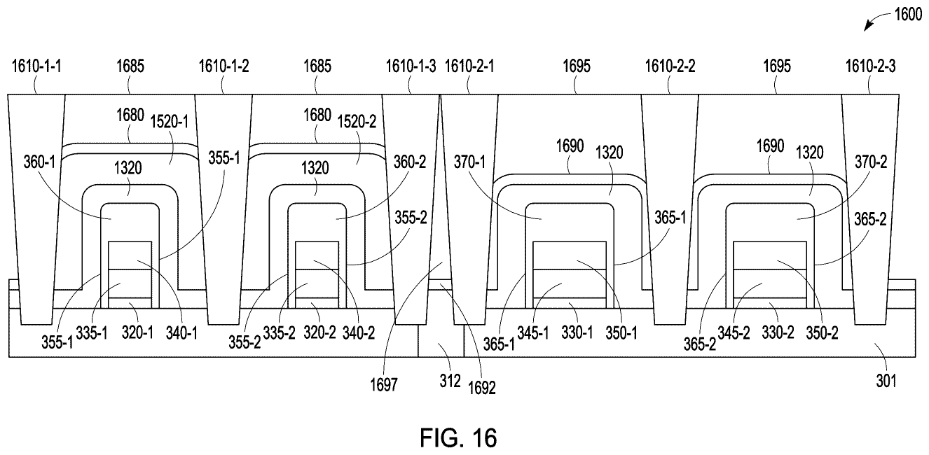

FIG. 16 represents a cross-sectional view of a structure 1600 after further processing structure 1500 of FIG. 15. Contact etch stop layer (CESL)/interlayer dielectrics (ILDs) deposition and contact formation have been performed. Contacts 1610-1-1 and 1610-1-2 for a first transistor of a CM OS device in periphery 302 have been formed, where the first transistor has gate structure 305-1. Contacts 1610-1-2 and 1610-1-3 for a second transistor of the CM OS device in periphery 302 have been formed, where the second transistor has gate structure 305-2. A dielectric region 1680 has been formed on and contacting stress nitride 1420 above gate structures 305-1 and 305-2 in periphery 302. Dielectric region 1680 can be composed of the same basic material as stress nitride 1420, except without being stressed. A n insulating region 1685 has been formed on dielectric region 1680. Insulating region 1685 can be an oxide having the composition of oxide liner 620, buffer oxide 1320, or other appropriate insulating oxide.

Contacts 1610-2-1 and 1610-2-2 for a first transistor of a CMOS device in sense amplifier 304 have been formed, where the first transistor has gate structure 305-3. Contacts 1610-2-2 and 1610-2-3 for a second transistor of the CM OS device in sense amplifier 304 have been formed, where the second transistor has gate structure 305-4. A dielectric region 1690 has been formed on and contacting buffer oxide 1320 above gate structures 305-3 and 305-4 in sense amplifier 304. Dielectric region 1690 can be composed of the same basic material as stress nitride 1420, except without being stressed. An insulating region 1695 has been formed on dielectric region 1690. Insulating region 1695 can be an oxide having the composition of oxide liner 620, buffer oxide 1320, or other appropriate insulating oxide.

Dielectric region 1692 has been formed above STI 312 and insulation region 1697 has been formed on dielectric region 1692. Dielectric region 1692 can have the composition of dielectric region 1680, dielectric region 1690, or other appropriate dielectric. Insulation region 1697 can have the composition of insulating region 1685, insulating region 1695, or other appropriate insulating material.

The processing of features of FIGS. 3-16, method 100, or method 200 can be conducted for multiple CM OS devices in periphery 302 and in multiple sense amplifiers 304. With such processing, most of the spacer between the gates of CM OS transistors and corresponding stress liners is oxide, which retains the benefit for RO performance. Various deposition techniques for forming components of these features can be used that are appropriate for the material being formed, the dimensions of the material being formed, and the architecture in which the material is being formed. Processes for forming the various materials can include, but are not limited to, chemical vapor deposition (CVD), atomic layer deposition (ALD), and physical vapor deposition (PVD). PVD can include, but is not limited to, sputtering, ion beam deposition, electron beam evaporation, pulsed laser deposition, and vacuum arc methods, among others. CVD can include, but is not limited to, plasma chemical vapor deposition and laser chemical vapor deposition, among others. Selective etching and conventional masking techniques can be used to remove selected regions in the processing. Selective etching is a process in which one or more materials are removed from a structure, while one or more other materials remain in the structure with no or little removal. Selective etching can depend on the material to be etched, the material not to be etched, the etchant employed, and the method for etching. Etching procedures can include, but are not limited to, wet etching, dry etching, and atomic layer etching deposition, among others, where each of these basic methods include a number of different etching procedures.

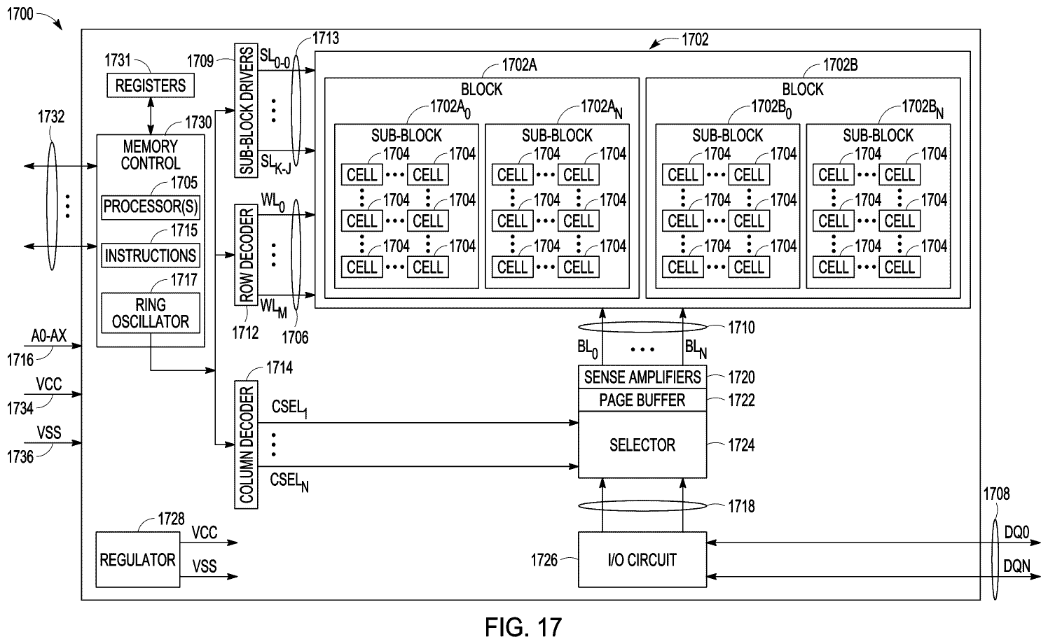

FIG. 17 illustrates a block diagram of an embodiment of an example memory device 1700 including a memory array 1702 having a plurality of memory cells 1704, a periphery to the array, sense amplifiers 1720, and one or more circuits or components to provide communication with memory array 1702 or perform one or more memory operations on memory array 1702. Memory device 1700 can include one or more CM OS devices in the periphery and one or more CMOS devices in sense amplifiers 1720 constructed and having a structure as discussed with respect to FIGS. 1-16. Memory cells 1704 can be formed coupled to data lines, where these data lines couple to or are a part of data lines 1710 coupled to sense amplifiers 1720. Memory device 1700 can be a memory die, for example, a DRAM memory die. Memory device 1700 can include a row decoder 1712, a column decoder 1714, sub-block drivers 1709, the sense amplifiers 1720, a page buffer 1722, a selector 1724, an I/O circuit 1726, and a memory controller 1730.

Memory controller 1730 can include processing circuitry, including one or more processors 1705, and can be configured to perform operations of the memory device 1700 by executing instructions 1715. Memory controller 1730 can be coupled to registers 1731 that can contain parameter data for the memory controller 1730. For purposes of the present example, the instructions 1715 may be performed by memory within or dedicated to memory controller 1730. In other examples, at least some portion of the instructions executed by memory controller 1730 may be stored in other memory structures and loaded, for example, into local (memory controller) memory for execution by the memory controller 1730. Memory controller 1730 can include a RO 1717. The RO performance can be measured by the RO speed in terms of delay time at fixed standby leakage, where lower delay time corresponds to higher RO performance.

Memory cells 1704 of memory array 1702 can be arranged in blocks, such as first and second blocks 1702A, 1702B. Each block can include sub-blocks. For example, first block 1702A can include first and second sub-blocks 1702A₀, 1702A_{N}, and second block 1702B can include first and second sub-blocks 1702B₀, 1702B_{N}. Each sub-block can include a number of physical pages, with each page including a number of memory cells 1704. Although illustrated herein as having two blocks, with each block having two sub-blocks, and each sub-block having a number of memory cells 1704, in other examples, the memory array 1702 can include more or fewer blocks, sub-blocks, memory cells, etc. In other examples, the memory cells 1704 can be arranged in a number of rows, columns, pages, sub-blocks, blocks, etc., and accessed using, for example, access lines 1706, data lines 1710, or one or more select gates, source lines, etc.

Memory controller 1730 can control memory operations of the memory device 1700 according to one or more signals or instructions received on control lines 1732, including, for example, one or more clock signals or control signals that indicate a desired operation (e.g., write, read, erase, etc.), or address signals (A0-AX) received on one or more address lines 1716. One or more devices external to memory device 1700 can control the values of the control signals on control lines 1732 or address signals on address line 1716. Examples of devices external to memory device 1700 can include, but are not limited to, a host, an external memory controller, a processor, or one or more circuits or components not illustrated in FIG. 17.

Memory device 1700 can use access lines 1706 and data lines 1710 to transfer data to (e.g., write or erase) or from (e.g., read) one or more of memory cells 1704. Row decoder 1712 and column decoder 1714 can receive and decode address signals (A0-AX) from address line 1716, determine which of memory cells 1704 are to be accessed, and provide signals to one or more of access lines 1706 (e.g., one or more of a plurality of access lines (WL₀-WL_{M})) or data lines 1710 (e.g., one or more of a plurality of data lines (BLO-BLN)). Memory device 1700 can include sense circuitry, such as sense amplifiers 1720, configured to determine the values of data on (e.g., read), or to determine the values of data to be written to, memory cells 1704 using data lines 1710.

One or more devices external to the memory device 1700 can communicate with memory device 1700 using I/O lines (DQ0-DQN) 1708, address lines 1716 (A0-AX), or control lines 1732. I/O circuit 1726 can transfer values of data in or out of memory device 1700, such as in or out of page buffer 1722 or memory array 1702, using I/O lines 1708, according to, for example, control lines 1732 and address lines 1716. Page buffer 1722 can store data received from the one or more devices external to memory device 1700 before the data is programmed into relevant portions of memory array 1702 or can store data read from memory array 1702 before the data is transmitted to the one or more devices external to the memory device 1700.

Column decoder 1714 can receive and decode address signals (A₀-A_{X}) into one or more column select signals (CSEL₁-CSEL_{N}). Selector 1724 (e.g., a select circuit) can receive the column select signals (CSEL₁-CSEL_{N}) and select data in page buffer 1722 representing values of data to be read from or to be programmed into memory cells 1704. Selected data can be transferred between page buffer 1722 and the I/O circuit 1726 using second data lines 1718.

Memory controller 1730 can receive positive and negative supply signals, such as a supply voltage (Vcc) 1734 and a negative supply (Vss) 1736 (e.g., a ground potential) with respect to Vcc, from an external source or supply (e.g., an internal or external battery, an alternating current (A C) to direct current (DC) converter, etc.). In certain examples, memory controller 1730 can include a regulator 1728 to internally provide positive or negative supply signals.

To program or write data to a memory cell, a programming voltage (e.g., one or more programming pulses, etc.) can be applied to selected access lines (e.g., WLᵢ), and, thus, to a control gate of each memory cell coupled to the selected access lines. Magnitude of the programming pulses depends on the architecture of memory device 1700. A pass voltage can be applied to one or more access lines having memory cells that are not targeted for programming, or an inhibit voltage (e.g., Vcc) can be applied to data lines having memory cells that are not targeted for programming. The pass voltage can be variable, depending on the architecture of memory device 1700. To erase a memory cell or a group of memory cells (e.g., erasure is typically performed in blocks or sub-blocks), an erasure voltage can be applied.

When a host, which is a user device, sends an address to memory device 1700, it typically can have an identification of a block, a page, and a column. The identification of the block is used to select the block of interest in the operation. The identification of the page is used to select the WL on which the page resides, and it also is used to select one particular sub-block, as the WL is shared among the sub-blocks of the block. The sub-block on which the page resides is decoded and that sub-block is selected. The address provided by the user device is used to turn on and off the selector device and access memory cells. In typical operations, one sub-block only is selected such that select devices of one sub-block are active.

Based on the address provided by the user device, memory controller 1730 can select any one sub-block or all sub-blocks. Memory controller 1730 can generate the sub-block address to the sub-block drivers 1709 and select any one sub-block or all sub-blocks. Memory controller 1730 can send the WL information to the row decoder 1712 and a column address to the column decoder 1714.

Sub-block drivers 1709 can include a number of independent drivers that generate signals to select lines 1713 SL₀₋₀ . . . . SL_{K-j}. These select lines can be coupled to different select devices in different blocks. Multiple input signals can be assigned to each individual driver, depending on the different voltages designed for operation of the respective driver during erase operations, program operations, and read operations. From the sub-block drivers 1709, appropriate operational signals can be sent to the memory array 1702 via the select lines 1713 (SL_{(sub-block #i-(SGD # or SGS #)}) SL₀₋₀ . . . . SL_{K-)}.

Electronic devices, such as mobile electronic devices (e.g., smart phones, tablets, etc.), electronic devices for use in automotive applications (e.g., automotive sensors, control units, driver-assistance systems, passenger safety or comfort systems, etc.), and internet-connected appliances or devices (e.g., internet-of-things (IoT) devices, etc.), have varying storage needs depending on, among other things, the type of electronic device, use environment, performance expectations, etc. In addition, electronic devices can be broken down into several main components: a processor (e.g., a central processing unit (CPU) or other main processor); memory (e.g., one or more volatile or non-volatile RAM memory devices, such as DRAM, mobile or low-power double-data-rate synchronous DRAM (DDR SDRAM), etc.); and a storage device (e.g., non-volatile memory (NVM) device, such as flash memory, ROM, a solid-state drive (SSD), a MultiMediaCard (MMC), or other memory card structure or assembly, etc.). In certain examples, electronic devices can include a user interface (e.g., a display, touch-screen, keyboard, one or more buttons, etc.), a graphics processing unit (GPU), a power management circuit, a baseband processor or one or more transceiver circuits, etc.

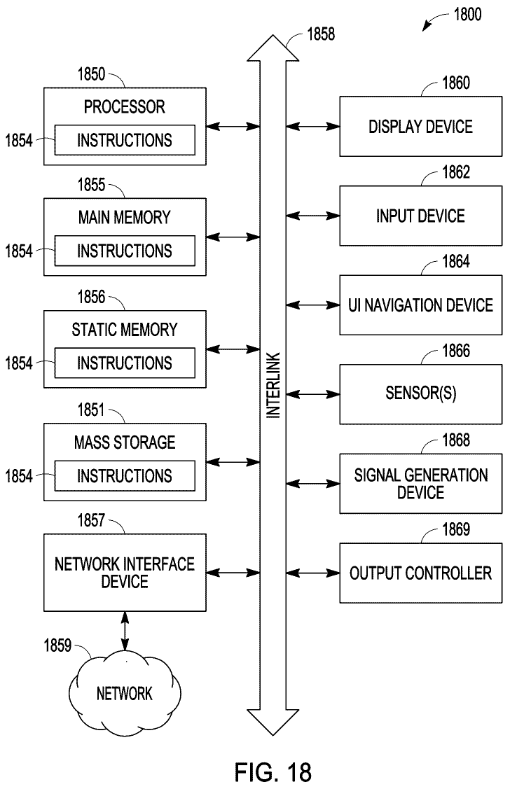

FIG. 18 illustrates a block diagram of an example machine 1800 upon which any one or more of the techniques (e.g., methodologies) discussed herein may be performed to implement formation of CMOS devices in the periphery to an array of memory cells and CM OS devices in sense amplifiers of one or more memory devices as discussed with respect to FIGS. 1-17, with the fabricated CMOS devices used within machine 1800. In alternative embodiments, machine 1800 may operate as a standalone device or may be connected (e.g., networked) to other machines. In a networked deployment, machine 1800 may operate in the capacity of a server machine, a client machine, or both in server-client network environments. In an example, machine 1800 may act as a peer machine in peer-to-peer (P2P) (or other distributed) network environment. Machine 1800 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform one or more methodologies, such as cloud computing, software as a service (Saas), other computer cluster configurations. The example machine 1800 can include CMOS devices as discussed with respect to FIGS. 1-17.

Machine 1800 may include a hardware processor 1850 (e.g., a CPU, a GPU, a hardware processor core, or any combination thereof), a main memory 1855, and a static memory 1856, some or all of which may communicate with each other via an interlink 1858 (e.g., bus). Machine 1800 may further include a display device 1860, an input device 1862, which can be an alphanumeric input device (e.g., a keyboard), and a user interface (UI) navigation device 1864 (e.g., a mouse). In an example, display device 1860, input device 1862, and UI navigation device 1864 may be a touch screen display. Machine 1800 may additionally include a mass storage device (e.g., drive unit) 1851, a signal generation device 1868, a network interface device 1857, and one or more sensors 1866, such as a global positioning system (GPS) sensor, compass, accelerometer, or other sensor. Machine 1800 may include an output controller 1869, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

Machine 1800 can store one or more sets of data structures or instructions 1854 (e.g., software) embodying or utilized by machine 1800 to perform any one or more of the techniques or functions for which machine 1800 is designed. Instructions 1854 may also reside, completely or at least partially, within main memory 1855, within static memory 1856, or within hardware processor 1850 during execution thereof by machine 1800.

Instructions 1854 (e.g., software, programs, an operating system (OS), etc.) or other data can be stored on mass storage device 1851 or can be accessed by main memory 1855 for use by hardware processor 1850. Main memory 1855 (e.g., DRAM) is typically fast, but volatile, and thus a different type of storage than mass storage device 1851 (e.g., an SSD), which is suitable for long-term storage, including while in an “off” condition. Instructions 1854 or data in use by a user or machine 1800 are typically loaded in main memory 1855 for use by hardware processor 1850. When main memory 1855 is full, virtual space from mass storage device 1851 can be allocated to supplement main memory 1855; however, because mass storage device 1851 is typically slower than main memory 1855, and write speeds are typically at least twice as slow as read speeds, use of virtual memory can greatly reduce user experience due to storage device latency (in contrast to main memory 1855, e.g., DRAM). Further, use of mass storage device 1851 for virtual memory can greatly reduce the usable lifespan of mass storage device 1851.

Storage devices optimized for mobile electronic devices, or mobile storage, traditionally include MMC solid-state storage devices (e.g., micro Secure Digital (microSD™) cards, etc.). MMC devices include a number of parallel interfaces (e.g., an 8-bit parallel interface) with a host device and are often removable and separate components from the host device. In contrast, embedded MMC (eMMC™) devices are attached to a circuit board and considered a component of the host device, with read speeds that rival Serial Advanced Technology Attachment (SATA)-based SSD devices. However, demand for mobile device performance continues to increase, such as to fully enable virtual or augmented-reality devices, utilize increasing networks speeds, etc. In response to this demand, storage devices have shifted from parallel to serial communication interfaces. Universal Flash Storage (UFS) devices, including controllers and firmware, communicate with a host device using a low-voltage differential signaling (LVDS) serial interface with dedicated read/write paths, further advancing greater read/write speeds.

Instructions 1854 can be transmitted or received over a network 1859 using a transmission medium via signal generation device 1868 or network interface device 1857 utilizing any one of a number of transfer protocols (e.g., frame relay, Internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, and peer-to-peer (P2P) networks, among others. In an example, signal generation device 1868 or network interface device 1857 may include one or more physical jacks (e.g., Ethernet, coaxial, or phone jacks) or one or more antennas to connect to network 1859. In an example, signal generation device 1868 or network interface device 1857 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any tangible medium that is capable of carrying instructions to and for execution by machine 1800, and includes instrumentalities to propagate digital or analog communications signals to facilitate communication of such instructions, which instructions may be implemented by software.

The following are example embodiments of electronic devices and methods, in accordance with the teachings herein.

An example memory device 1 can comprise an array of memory cells, a first transistor in a periphery to the array, and a second transistor in the periphery to the array. The first transistor can include: a first gate structure having a first dielectric sidewall; a first oxide sidewall on and contacting the first dielectric sidewall, the first oxide sidewall being larger than the first dielectric sidewall; and a first stress liner on and contacting the first oxide sidewall, the first stress liner being a dielectric. The second transistor can include: a second gate structure having a second dielectric sidewall; a second oxide sidewall on and contacting the second dielectric sidewall, the second oxide sidewall being larger than the second dielectric sidewall; and a second stress liner on and contacting the second oxide sidewall, the second stress liner being a dielectric.

An example memory device 2 can include features of example memory device 1 and can include a third transistor in a sense amplifier to the array and a fourth transistor in the sense amplifier to the array. The third transistor can include: a third gate structure having a third dielectric sidewall; and a third oxide sidewall on and contacting the third dielectric sidewall, the third oxide sidewall arranged without a stress liner on and contacting the third oxide sidewall. The fourth transistor can include: a fourth gate structure having a fourth dielectric sidewall; and a fourth oxide sidewall on and contacting the fourth dielectric sidewall, the fourth oxide sidewall arranged without a stress liner on and contacting the fourth oxide sidewall.

An example memory device 3 can include features of example memory device 2 and any of the preceding example memory devices and can include the first transistor and the second transistor being transistors of a first CM OS device and the third transistor and the fourth transistor being transistors of a second CM OS device.

An example memory device 4 can include features of example memory device 2 and any of the preceding example memory devices and can include the first oxide sidewall and the second oxide sidewall having a common composition that is also located between the first oxide sidewall and the second oxide sidewall on a surface to source and drain regions of the first and second transistors.

An example memory device 5 can include features of example memory device 4 and any of the preceding example memory devices and can include the third oxide sidewall and the fourth oxide sidewall having the common composition that is also located between the third oxide sidewall and the fourth oxide sidewall on a surface to source and drain regions of the first and second transistors.

An example memory device 6 can include features of any of the preceding example memory devices and can include each of the first oxide sidewall and the second oxide sidewall to include silicon oxide.

An example memory device 7 can include features of any of the preceding example memory devices and can include each of the first stress liner and the second stress liner to include a tensile nitride.

An example memory device 8 can include features of example memory device 7 and any of the preceding example memory devices and can include the tensile nitride being a tensile silicon nitride.

In an example memory device 9, any of the memory devices of example memory devices 1 to 8 may include components incorporated into an electronic apparatus further comprising one or more host processors and a communication bus extending between the one or more host processors and the memory device.

In an example memory device 10, any of the memory devices of example memory devices 1 to 9 may be modified to include any structure presented in another of example memory device 1 to 9.

In an example memory device 11, any apparatus associated with the memory devices of example memory devices 1 to 10 may further include a machine-readable storage device configured to store instructions as a physical state, wherein the instructions may be used to perform one or more operations of the apparatus.

In an example memory device 12, any of the memory devices of example memory devices 1 to 6 may be formed in accordance with any of the below example methods 1 to 9.

An example method 1 of forming a memory device can comprise forming an array of memory cells, forming a first transistor in a periphery to the array, and forming a second transistor in a periphery to the array. Forming a first transistor in a periphery to the array, can include:

forming a first gate structure having a first dielectric sidewall; forming a first oxide sidewall on and contacting the first dielectric sidewall, with the first oxide sidewall being formed larger than the first dielectric sidewall; and forming a first stress liner on and contacting the first oxide sidewall, the first stress liner being a dielectric. Forming a second transistor in the periphery to the array can include: forming a second gate structure having a second dielectric sidewall; forming a second oxide sidewall on and contacting the second dielectric sidewall, the second oxide sidewall being larger than the second dielectric sidewall; and forming a second stress liner on and contacting the second oxide sidewall, the second stress liner being a dielectric.

An example method 2 of forming a memory device can include features of example method 1 of forming a memory device and can include forming a third transistor in a sense amplifier to the array and forming a fourth transistor in a sense amplifier to the array. Forming a third transistor in a sense amplifier to the array can include: forming a third gate structure having a third dielectric sidewall; and forming a third oxide sidewall on and contacting the third dielectric sidewall, the third oxide sidewall arranged without a stress liner on and contacting completion of the third oxide sidewall. Forming a fourth transistor in the sense amplifier to the array can include forming a fourth gate structure having a fourth dielectric sidewall; and forming a fourth oxide sidewall on and contacting the fourth dielectric sidewall, the fourth oxide sidewall arranged without a stress liner on and contacting completion of the fourth oxide sidewall.

An example method 3 of forming a memory device can include features of example method 2 of forming a memory device and any of the preceding example methods of forming a memory device and can include forming the first transistor and the second transistor as a first complementary metal oxide semiconductor device in the periphery and forming the third transistor and the fourth transistor as a second complementary metal oxide semiconductor device in the sense amplifier.

An example method 4 of forming a memory device can include features of example method 2 of forming a memory device and any of the preceding example methods of forming a memory device and can include forming the first oxide sidewall, the second oxide sidewall, the third oxide sidewall, and the fourth oxide sidewall having a common composition and formed in a common fabrication process.

An example method 5 of forming a memory device can include features of example method 4 of forming a memory device and any of the preceding example methods of forming a memory device and can include forming a stress dielectric on the first oxide sidewall, the second oxide sidewall, the third oxide sidewall, and the fourth oxide sidewall; and removing the stress dielectric from the third oxide sidewall, and the fourth oxide sidewall.

An example method 6 of forming a memory device can include features of example method 4 of forming a memory device and any of the preceding example methods of forming a memory device and can include the common composition being silicon oxide and the stress liner can include a tensile nitride.

In an example method 7 of forming a memory device, any of the example methods 1 to 6 of forming a memory device may be performed in forming an electronic apparatus further comprising a host processor and a communication bus extending between the host processor and a memory system.

In an example method 8 of forming a memory device, any of the example methods 1 to 7 of forming a memory device may be modified to include operations set forth in any other of example methods 1 to 7 of forming a memory device.

In an example method 9 of forming a memory device, any of the example methods 1 to 8 of forming a memory device may be implemented at least in part through use of instructions stored as a physical state in one or more machine-readable storage devices.

An example method 10 of forming a memory device can include features of any of the preceding example methods 1 to 9 of forming a memory device and can include performing functions associated with any features of example memory devices 1 to 12.

An example method 11 of forming a memory device can comprise: forming two gate structures of transistors of a CM OS device in a periphery to an array of memory cells and forming two gate structures of transistors of a CM OS device in a sense amplifier to the array of memory cells; forming an oxide liner on the two gate structures of the CM OS device in the periphery and on the two gate structures of the CM OS device in the sense amplifier; forming a first nitride spacer on the oxide liner on the two gate structures of the CM OS device in the periphery and a second nitride spacer on the oxide liner on the two gate structures of the CM OS device in the sense amplifier; doping sources and drains of the CM OS device in the periphery and the CMOS device in the sense amplifier, using the first nitride spacer and the second nitride spacer; removing the first nitride spacer and the second nitride spacer, exposing the oxide liner on the two gate structures of the CMOS device in the periphery and exposing the oxide liner on the two gate structures of the CM OS device in the sense amplifier; forming a buffer oxide on the exposed oxide liner on the two gate structures of the CM OS device in the periphery and on the exposed oxide liner on the two gate structures of the CM OS device in the sense amplifier; forming a stress nitride on the buffer oxide on the two gate structures of the CM OS device in the periphery, and exposing the buffer oxide on the two gate structures of the CM OS device in the sense amplifier without a stress nitride; and providing electrical contacts to the CM OS device in the periphery and to the CM OS device in the sense amplifier, after forming the stress nitride and exposing the buffer oxide.

An example method 12 of forming a memory device can include features of example method 11 of forming a memory device and can include forming a spacer for lightly doped drains to the transistors of the CM OS device in the periphery and for lightly doped drains to the transistors of the CM OS device in the sense amplifier; removing the spacer for the lightly doped drains from horizontal surfaces between the transistors of the CM OS device in the periphery and from horizontal surfaces between the transistors of the CM OS device in the sense amplifier; and forming lightly doped drain implants between the transistors of the CM OS device in the periphery and between the transistors of the CMOS device in the sense amplifier.

An example method 13 of forming a memory device can include features of any of the preceding example methods of forming a memory device and can include forming the first nitride spacer and the second nitride spacer to include: forming a first nitride region on the oxide liner on the two gate structures of the CM OS device in the periphery, on the oxide liner on the two gate structures of the CM OS device in the sense amplifier, on horizontal surface between the two gate structures of the CM OS device in the periphery, and on horizontal surfaces between the two gate structures of the CM OS device in the sense amplifier; removing the first nitride region from the horizontal surface between the two gate structures of the CM OS device in the periphery and from the sense amplifier; forming a second nitride region on the first nitride region on the oxide liner on the two gate structures of the CM OS device in the periphery, on the horizontal surface between the two gate structures of the CM OS device in the periphery, on the horizontal surface between the two gate structures of the CM OS device in the sense amplifier, and on the oxide liner on the two gate structures of the CM OS device in the sense amplifier; and removing the second nitride region from the horizontal surface between the two gate structures of the CM OS device in the periphery and from the horizontal surface between the two gate structures of the CM OS device in the sense amplifier.

An example method 14 of forming a memory device can include features of any of the preceding example methods of forming a memory device and can include forming the stress nitride in the periphery and exposing the buffer oxide in the sense amplifier without a stress nitride to include: forming a stress nitride region above and between the gate structures of the CM OS device in the periphery and above and between the gate structures of the CM OS device in the sense amplifier; and removing the stress nitride region from between the gate structures of the CMOS device in the periphery and from the sense amplifier.

An example method 15 of forming a memory device can include features of any of the preceding example methods of forming a memory device and can include forming the stress nitride to include forming a tensile nitride.

An example method 16 of forming a memory device can include features of any of the preceding example methods of forming a memory device and can include forming the stress nitride on the buffer oxide on the two gate structures of the CM OS device in the sense amplifier; forming the stress nitride on a horizontal surface between the two gate structures of the CM OS device in the periphery and on a horizontal surface between the two gate structures of the CMOS device in the sense amplifier; removing the stress nitride from the buffer oxide on the two gate structures of the CMOS device in the sense amplifier and from the horizontal surface between the two gate structures of the CM OS device in the periphery and from the horizontal surface between the two gate structures of the CM OS device in the sense amplifier; forming a nitride region on the stress nitride in the CM OS device in the sense amplifier and on the buffer oxide on the two gate structures of the CMOS device in the sense amplifier; and forming the electrical contacts through the nitride region and the buffer oxide on the horizontal surfaces between the two transistors of the CM OS device in the periphery and the two transistors of the CM OS device in the sense amplifier.

In an example method 17 of forming a memory device, any of the example methods 11 to 16 of forming a memory device may be performed in forming an electronic apparatus further comprising a host processor and a communication bus extending between the host processor and a memory system.

In an example method 18 of forming a memory device, any of the example methods 11 to 17 of forming a memory device may be modified to include operations set forth in any other of example methods 11 to 17 of forming a memory device.

In an example method 19, any of the example methods 11 to 18 of forming a memory device may be implemented at least in part through use of instructions stored as a physical state in one or more machine-readable storage devices.

An example method 20 of forming a memory device can include features of any of the preceding example methods 11 to 19 of forming a memory device and can include performing functions associated with any features of example memory devices 1 to 12.

An example machine-readable storage device storing instructions, that when executed by one or more processors, cause a machine to perform operations, can comprise instructions to perform functions associated with any features of example memory devices 1 to 12 or perform methods associated with any features of example methods 1 to 20 of forming a memory device.

Although specific embodiments have been illustrated and described herein, any arrangement that is calculated to achieve the same purpose may be substituted for the specific embodiments shown. Various embodiments can use permutations and/or combinations of embodiments described herein. The above description is intended to be illustrative, and not restrictive, and that the phraseology or terminology employed herein is for the purpose of description.

What is claimed is:

1. A memory device comprising:
an array of memory cells;
a first transistor in a periphery to the array, the first transistor including:
a first gate structure having a first dielectric sidewall;
a first oxide sidewall on and contacting the first dielectric sidewall, the first oxide sidewall being larger than the first dielectric sidewall; and
a first stress liner on and contacting the first oxide sidewall, the first stress liner being a dielectric; and
a second transistor in the periphery to the array, the second transistor including:
a second gate structure having a second dielectric sidewall;
a second oxide sidewall on and contacting the second dielectric sidewall, the second oxide sidewall being larger than the second dielectric sidewall; and
a second stress liner on and contacting the second oxide sidewall, the second stress liner being a dielectric.

2. The memory device of claim 1, wherein the memory device includes:
a third transistor in a sense amplifier to the array, the third transistor including:
a third gate structure having a third dielectric sidewall; and
a third oxide sidewall on and contacting the third dielectric sidewall, the third oxide sidewall arranged without a stress liner on and contacting the third oxide sidewall; and
a fourth transistor in the sense amplifier to the array, the fourth transistor including:
a fourth gate structure having a fourth dielectric sidewall; and
a fourth oxide sidewall on and contacting the fourth dielectric sidewall, the fourth oxide sidewall arranged without a stress liner on and contacting the fourth oxide sidewall.

3. The memory device of claim 2, wherein the first transistor and the second transistor are transistors of a first complementary metal oxide semiconductor device and the third transistor and the fourth transistor are transistors of a second complementary metal oxide semiconductor device.

4. The memory device of claim 2, wherein the first oxide sidewall and the second oxide sidewall have a common composition that is also located between the first oxide sidewall and the second oxide sidewall on a surface to source and drain regions of the first and second transistors.

5. The memory device of claim 4, wherein the third oxide sidewall and the fourth oxide sidewall have the common composition that is also located between the third oxide sidewall and the fourth oxide sidewall on a surface to source and drain regions of the first and second transistors.

6. The memory device of claim 1, wherein each of the first oxide sidewall and the second oxide sidewall include silicon oxide.

7. A memory device of claim 1, wherein each of the first stress liner and the second stress liner include a tensile nitride.

8. A memory device of claim 7, wherein the tensile nitride is a tensile silicon nitride.

9. A method of forming a memory device, the method comprising:
forming an array of memory cells;
forming a first transistor in a periphery to the array, including:
forming a first gate structure having a first dielectric sidewall;
forming a first oxide sidewall on and contacting the first dielectric sidewall, with the first oxide sidewall being formed larger than the first dielectric sidewall; and
forming a first stress liner on and contacting the first oxide sidewall, the first stress liner being a dielectric;
forming a second transistor in the periphery to the array, including:
forming a second gate structure having a second dielectric sidewall;
forming a second oxide sidewall on and contacting the second dielectric sidewall, the second oxide sidewall being larger than the second dielectric sidewall; and
forming a second stress liner on and contacting the second oxide sidewall, the second stress liner being a dielectric.

10. The method of claim 9, wherein the method includes:
forming a third transistor in a sense amplifier to the array, including:
forming a third gate structure having a third dielectric sidewall; and
forming a third oxide sidewall on and contacting the third dielectric sidewall, the third oxide sidewall arranged without a stress liner on and contacting completion of the third oxide sidewall; and
forming a fourth transistor in the sense amplifier to the array, including:
forming a fourth gate structure having a fourth dielectric sidewall; and
forming a fourth oxide sidewall on and contacting the fourth dielectric sidewall, the fourth oxide sidewall arranged without a stress liner on and contacting completion of the fourth oxide sidewall.

11. The method of claim 10, wherein the method includes forming the first transistor and the second transistor as a first complementary metal oxide semiconductor device in the periphery and forming the third transistor and the fourth transistor as a second complementary metal oxide semiconductor device in the sense amplifier.

12. The method of claim 10, wherein the method includes forming the first oxide sidewall, the second oxide sidewall, the third oxide sidewall, and the fourth oxide sidewall having a common composition and formed in a common fabrication process.

13. The method of claim 12, wherein the method includes:
forming a stress dielectric on the first oxide sidewall, the second oxide sidewall, the third oxide sidewall, and the fourth oxide sidewall; and
removing the stress dielectric from the third oxide sidewall, and the fourth oxide sidewall.

14. The method of claim 12, wherein the common composition is silicon oxide and the stress liner include a tensile nitride.

15. A method of forming a memory device, the method comprising:
forming two gate structures of transistors of a complementary metal oxide semiconductor (CM OS) device in a periphery to an array of memory cells and forming two gate structures of transistors of a CM OS device in a sense amplifier to the array of memory cells;
forming an oxide liner on the two gate structures of the CM OS device in the periphery and on the two gate structures of the CM OS device in the sense amplifier;
forming a first nitride spacer on the oxide liner on the two gate structures of the CMOS device in the periphery and a second nitride spacer on the oxide liner on the two gate structures of the CMOS device in the sense amplifier;
doping sources and drains of the CM OS device in the periphery and the CMOS device in the sense amplifier, using the first nitride spacer and the second nitride spacer;
removing the first nitride spacer and the second nitride spacer, exposing the oxide liner on the two gate structures of the CM OS device in the periphery and exposing the oxide liner on the two gate structures of the CM OS device in the sense amplifier;
forming a buffer oxide on the exposed oxide liner on the two gate structures of the CMOS device in the periphery and on the exposed oxide liner on the two gate structures of the CM OS device in the sense amplifier;
forming a stress nitride on the buffer oxide on the two gate structures of the CMOS device in the periphery, and exposing the buffer oxide on the two gate structures of the CM OS device in the sense amplifier without a stress nitride; and
providing electrical contacts to the CM OS device in the periphery and to the CM OS device in the sense amplifier, after forming the stress nitride and exposing the buffer oxide.

16. The method of claim 15, wherein the method includes:
forming a spacer for lightly doped drains to the transistors of the CM OS device in the periphery and for lightly doped drains to the transistors of the CMOS device in the sense amplifier;
removing the spacer for the lightly doped drains from horizontal surfaces between the transistors of the CM OS device in the periphery and from horizontal surfaces between the transistors of the CM OS device in the sense amplifier; and
forming lightly doped drain implants between the transistors of the CMOS device in the periphery and between the transistors of the CMOS device in the sense amplifier.

17. The method of claim 15, wherein forming the first nitride spacer and the second nitride spacer includes:
forming a first nitride region on the oxide liner on the two gate structures of the CMOS device in the periphery, on the oxide liner on the two gate structures of the CMOS device in the sense amplifier, on horizontal surface between the two gate structures of the CM OS device in the periphery, and on horizontal surfaces between the two gate structures of the CM OS device in the sense amplifier;
removing the first nitride region from the horizontal surface between the two gate structures of the CM OS device in the periphery and from the sense amplifier;
forming a second nitride region on the first nitride region on the oxide liner on the two gate structures of the CMOS device in the periphery, on the horizontal surface between the two gate structures of the CM OS device in the periphery, on the horizontal surface between the two gate structures of the CM OS device in the sense amplifier, and on the oxide liner on the two gate structures of the CMOS device in the sense amplifier; and
removing the second nitride region from the horizontal surface between the two gate structures of the CM OS device in the periphery and from the horizontal surface between the two gate structures of the CM OS device in the sense amplifier.

18. The method of claim 15, wherein forming the stress nitride in the periphery and exposing the buffer oxide in the sense amplifier without a stress nitride includes:
forming a stress nitride region above and between the gate structures of the CM OS device in the periphery and above and between the gate structures of the CMOS device in the sense amplifier; and
removing the stress nitride region from between the gate structures of the CM OS device in the periphery and from the sense amplifier.

19. The method of claim 15, wherein forming the stress nitride includes forming a tensile nitride.

20. The method of claim 15, wherein the method includes:
forming the stress nitride on the buffer oxide on the two gate structures of the CM OS device in the sense amplifier;
forming the stress nitride on a horizontal surface between the two gate structures of the CM OS device in the periphery and on a horizontal surface between the two gate structures of the CM OS device in the sense amplifier;
removing the stress nitride from the buffer oxide on the two gate structures of the CMOS device in the sense amplifier and from the horizontal surface between the two gate structures of the CM OS device in the periphery and from the horizontal surface between the two gate structures of the CM OS device in the sense amplifier;
forming a nitride region on the stress nitride in the CM OS device in the sense amplifier and on the buffer oxide on the two gate structures of the CM OS device in the sense amplifier; and
forming the electrical contacts through the nitride region and the buffer oxide on the horizontal surfaces between the two transistors of the CM OS device in the periphery and the two transistors of the CMOS device in the sense amplifier.
